(19) United States
(12) Patent Application Publication
(10) Pub. No.: US 2026/0088771 A1
(43) Pub. Date: Mar. 26, 2026

(54) Adaptive Biasing for Multipath Radio-Frequency Amplifiers

(71) Applicant: Apple Inc., Cupertino, CA (US)

(72) Inventors: Jong Seok Park, San Diego, CA (US); Morteza Nick, San Diego, CA (US); Youngchang Yoon, San Diego, CA (US)

(21) Appl. No.: 18/897,557

(22) Filed: Sep. 26, 2024

(51) Int. Cl. H03F 1/02; H03F 1/30

(52) U.S. Cl. CPC H03F 1/0288; H03F 1/30; H03F 2200/451; H03F 2200/471

(57) ABSTRACT

An electronic device may be provided with an antenna fed using a Doherty amplifier. The Doherty amplifier may include a main amplifier path with a main amplifier and an auxiliary amplifier path with an auxiliary amplifier. An adaptive biasing circuit may be coupled to the main amplifier path around the main amplifier. The adaptive biasing circuit may include a first voltage detector coupled to an input of the main amplifier, a second voltage detector coupled to an output of the main amplifier, and a subtractor. The first voltage detector may measure an input voltage of the main amplifier. The second voltage detector may measure an output voltage of the main amplifier. The subtractor may generate a difference voltage between the input and output voltages. The auxiliary amplifier may be biased using the difference voltage.

### FIELD

This disclosure relates generally to electronic devices, including electronic devices with wireless communications circuitry.

### BACKGROUND

Electronic devices are often provided with wireless communications capabilities. An electronic device with wireless communications capabilities has wireless communications circuitry with one or more antennas. Wireless transceiver circuitry in the wireless communications circuitry uses the antennas to transmit and receive radio-frequency signals.

Radio-frequency signals transmitted by an antenna are often fed through one or more power amplifiers, which are configured to amplify low power analog signals to higher power signals more suitable for transmission through the air over long distances. It can be challenging to design a satisfactory power amplifier for an electronic device.

### SUMMARY

An electronic device may be provided with wireless circuitry. The wireless circuitry may include an antenna. The wireless circuitry may include a Doherty amplifier communicatively coupled to the antenna. The Doherty amplifier may include an input network, an output network, a main amplifier path between the input and output networks, and one or more auxiliary amplifier paths coupled between the input and output networks in parallel with the main amplifier path. The main amplifier path may include a main amplifier. The auxiliary amplifier path may include an auxiliary amplifier.

An adaptive biasing circuit may be coupled to the main amplifier path around the main amplifier. The adaptive biasing circuit may include a first voltage detector operably coupled to an input of the main amplifier, a second voltage detector operably coupled to an output of the main amplifier, an attenuator coupled between the second voltage detector and the output of the main amplifier, and a subtractor coupled to the first and second voltage detectors. The first voltage detector may measure an input voltage level of the main amplifier. The second voltage detector may measure an output voltage level of the main amplifier. The subtractor may generate a difference voltage between the input and output voltage levels. The auxiliary amplifier may be biased using the difference voltage. This may ensure that the auxiliary amplifier turns on at the most efficient point for the Doherty amplifier without sacrificing performance given the impedance of the antenna, operating temperature, and process variation.

An aspect of the disclosure provides amplifier circuitry. The amplifier circuitry can include an input circuit. The amplifier circuitry can include an output circuit. The amplifier circuitry can include a first amplifier path coupled between the input and output circuits and having a first amplifier. The amplifier circuitry can include a second amplifier path coupled between the input and output circuits and having a second amplifier. The amplifier circuitry can include a first voltage detector operably coupled an input of the first amplifier. The amplifier circuitry can include a second voltage detector operably coupled to an output of the first amplifier. The amplifier circuitry can include a subtractor having an input coupled to the first and second voltage detectors. The amplifier circuitry can include a bias voltage path that couples an output of the subtractor to a bias terminal of the second amplifier.

An aspect of the disclosure provides amplifier circuitry. The amplifier circuitry can include an input network. The amplifier circuitry can include an output network. The amplifier circuitry can include a primary amplifier path coupled between the input and output networks. The amplifier circuitry can include a first amplifier on the primary amplifier path.

The amplifier circuitry can include an auxiliary amplifier path coupled between the input and output networks in parallel with the primary amplifier path. The amplifier circuitry can include a second amplifier on the auxiliary amplifier path. The amplifier circuitry can include an adaptive biasing circuit configured to bias the second amplifier based on an output voltage level of the first amplifier and based on an input voltage level of the first amplifier.

An aspect of the disclosure provides wireless circuitry. The wireless circuitry can include an antenna. The wireless circuitry can include a power amplifier communicatively coupled to the antenna and configured to transmit a radio-frequency signal using the antenna.

The power amplifier can include a signal splitter. The power amplifier can include a signal combiner. The power amplifier can include a first amplifier path coupled between the signal splitter and the signal combiner and having a first amplifier. The power amplifier can include a second amplifier path coupled between the signal splitter and the signal combiner in parallel with the first amplifier path and having a second amplifier. The power amplifier can include a first voltage detector configured to measure an input voltage of the first amplifier. The power amplifier can include a second voltage detector configured to measure an output voltage of the first amplifier, wherein the second amplifier is biased using a difference between the input voltage and the output voltage of the first amplifier.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry that includes amplifier circuitry in accordance with some embodiments.

FIG. 3 is a block diagram of illustrative multipath amplifier circuitry in accordance with some embodiments.

FIG. 4 is a circuit diagram of illustrative multipath amplifier circuitry that includes adaptive biasing circuitry in accordance with some embodiments.

FIG. 5 plots different voltages that are associated with illustrative adaptive biasing circuitry in accordance with some embodiments.

FIG. 6 is a circuit diagram of illustrative multipath amplifier circuitry that includes adaptive biasing circuitry for multiple auxiliary amplifier paths in accordance with some embodiments.

FIG. 7 plots the bias voltage produced by illustrative adaptive biasing circuitry under different output loads in accordance with some embodiments.

### DETAILED DESCRIPTION

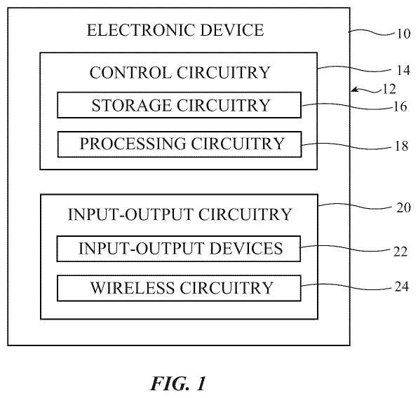

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses, goggles, a helmet, or other equipment worn on a user's head (e.g., an augmented, virtual, or mixed reality head-mounted display device), or another wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more processors such as microprocessors, microcontrollers, digital signal processors, host processors, baseband processor integrated circuits, application specific integrated circuits, central processing units (CPUs), graphics processing units (GPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 3GPP Fifth Generation (5G) New Radio (NR) protocols, Sixth Generation (6G) protocols, sub-THz protocols, THz protocols, etc.), antenna diversity protocols, satellite navigation system protocols (e.g., global positioning system (GPS) protocols, global navigation satellite system (GLONASS) protocols, etc.), antenna-based spatial ranging protocols, optical communications protocols, or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), a Wi-Fi® 7 band, and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), other centimeter or millimeter wave frequency bands between 10-100 GHz, sub-THz frequency bands between around 100 GHz and 10 THz (e.g., 6G bands), near-field communications (NFC) frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

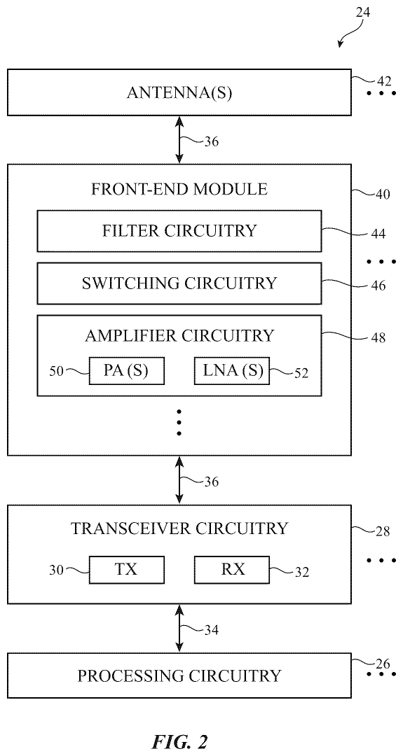

FIG. 2 is a diagram showing illustrative components within wireless circuitry 24. As shown in FIG. 2, wireless circuitry 24 may include processing circuitry such as processing circuitry 26, radio-frequency (RF) transceiver circuitry such as radio-frequency transceiver 28, radio-frequency front-end circuitry such as radio-frequency front-end module (FEM) 40, and antenna(s) 42. Processing circuitry 26 may be coupled to transceiver 28 over baseband path 34. Transceiver 28 may be coupled to antenna 42 via radio-frequency transmission line path 36. Radio-frequency front-end module 40 may be disposed on radio-frequency transmission line path 36 between transceiver 28 and antenna 42.

In the example of FIG. 2, wireless circuitry 24 is illustrated as including only a single transceiver 28, a single front-end module 40, and a single antenna 42 for the sake of clarity. In general, wireless circuitry 24 may include any desired number of transceivers 28, any desired number of front-end modules 40, and any desired number of antennas 42. If desired, processing circuitry 26 may include different processing units (e.g., processors) coupled to one or more transceiver 28 over respective baseband paths 34. Each transceiver 28 may include a transmitter (TX) circuit 30 configured to output uplink signals to antenna 42, may include a receiver (RX) circuit 32 configured to receive downlink signals from antenna 42, and may be coupled to one or more antennas 42 over respective radio-frequency transmission line paths 36. Each radio-frequency transmission line path 36 may have a respective front-end module 40 disposed thereon. If desired, two or more front-end modules 40 may be disposed on the same radio-frequency transmission line path 36. If desired, one or more of the radio-frequency transmission line paths 36 in wireless circuitry 24 may be implemented without any front-end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is merely illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processing circuitry 26 may provide baseband signals to transceiver 28 over baseband path 34. Transceiver 28 may further include circuitry for converting the baseband signals received from processing circuitry 26 into corresponding radio-frequency signals. For example, transceiver circuitry 28 may include mixer circuitry for up-converting (or modulating) the baseband signals to radio-frequencies prior to transmission over antenna 42. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front-end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front-end module 40. Transceiver 28 may include circuitry such as receiver (RX) 32 for receiving signals from front-end module 40 and for converting the received radio-frequency signals into corresponding baseband signals. For example, transceiver 28 may include mixer circuitry for down-converting (or demodulating) the received radio-frequency signals to baseband frequencies prior to conveying the received signals to processing circuitry 26 over baseband path 34.

Front-end module (FEM) 40 may include radio-frequency front-end circuitry that operates on the radio-frequency signals conveyed (transmitted and/or received) over radio-frequency transmission line path 36. FEM 40 may, for example, include front-end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front-end module components may be mounted to a common (shared) substrate such as a rigid printed circuit board substrate or flexible printed circuit substrate. If desired, the various front-end module components may also be integrated into a single integrated circuit chip.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front-end module 40. For example, transceiver 28 may be formed on another substrate such as the main logic board of device 10, a rigid printed circuit board, or flexible printed circuit that is not a part of front-end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processing circuitry 26 and/or portions of transceiver 28 (e.g., a host processor on transceiver 28) may form a part of control circuitry 14. Control circuitry 14 (e.g., portions of control circuitry 14 formed on processing circuitry 26, portions of control circuitry 14 formed on transceiver 28, and/or portions of control circuitry 14 that are separate from wireless circuitry 24) may provide control signals (e.g., over one or more control paths in device 10) that control the operation of front-end module 40.

Transceiver 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), a Wi-Fi® 7 band, wireless personal area network (WPAN) transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, 6G bands above 100 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

As described above, front-end module 40 may include one or more power amplifiers (PA) circuits 50 in the transmit (uplink) path. A power amplifier 50 (sometimes referred to as radio-frequency power amplifier circuitry, transmit amplifier circuitry, or amplifier circuitry) may be configured to amplify a radio-frequency signal without changing the signal shape, format, or modulation. Power amplifier 50 may, for example, be used to provide 10 dB of gain, 20 dB of gain, 10-20 dB of gain, less than 20 dB of gain, more than 20 dB of gain, or other suitable amounts of gain.

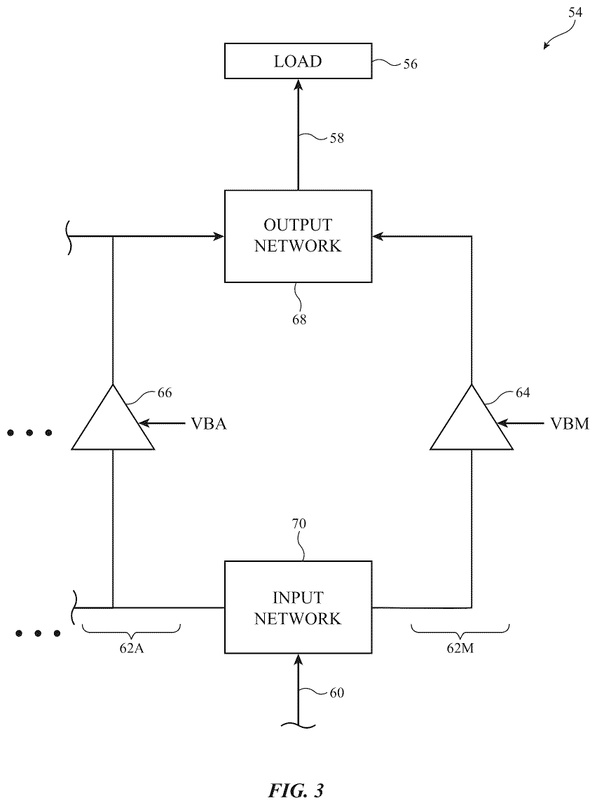

In implementations that are described herein as an example, one or more amplifiers in wireless circuitry 24 may include multipath amplifier circuitry. Multipath amplifier circuitry may include a main amplifier path and one or more auxiliary amplifier paths coupled in parallel between an input path and an output load. FIG. 3 is a diagram of illustrative multipath amplifier circuitry 54 that may be used in wireless circuitry 24. Multipath amplifier circuitry 54 of FIG. 3 may, for example, form a PA 50 in front end module 40, a PA in transceiver 28, an LNA 52 in front end module 40, an LNA in transceiver 28, or any other desired radio-frequency amplifier elsewhere in wireless circuitry 24.

As shown in FIG. 3, multipath amplifier circuitry 54 may be coupled between an input signal path 60 and an output signal path 58. While referred to herein as input signal path 60 and output signal path 58, input signal path 60 and output signal path 58 may be formed from respective portions of the same signal path in wireless circuitry 24 (e.g., may form respective portions of a radio-frequency transmission line path 36 of FIG. 2). Output signal path 58 may be coupled to an output load such as load 56. Load 56 may be, for example, an antenna 42 (FIG. 2), other circuitry in a transmit chain coupled to an antenna 42, or any other desired load in wireless circuitry 24.

Multipath amplifier circuitry 54 may include input circuitry such as input network 70 (e.g., an input matching network). Input network 70 may have an input terminal (port) coupled to input signal path 60. Multipath amplifier circuitry 54 may include output circuitry such as output network 68 (e.g., an output matching network). Output network 68 may have an output terminal (port) coupled to signal path 58. The input terminal of input network 70 may form the input of multipath amplifier circuitry 54. The output terminal of output network 68 may form the output of multipath amplifier circuitry 54.

Multipath amplifier circuitry 54 may include a set of two or more amplifier paths 62 coupled in parallel between respective output terminals (ports) of input network 70 and respective input terminals (ports) of output network 68. Input network 70 may receive a radio-frequency signal over input signal path 60. Input network 70 may include signal splitting circuitry (e.g., a balanced signal splitter, quadrature hybrid splitting circuitry, matching circuitry, etc.) that splits the radio-frequency signal received from input signal path 60 between amplifier paths 62. Each amplifier path 62 may include one or more respective amplifiers that amplify the radio-frequency signal and that provide the amplified radio-frequency signal to output network 68. Output network 68 may include signal combining circuitry (e.g., a balanced signal combiner, one or more transformers, baluns, matching circuitry, etc.) that combines the amplified radio-frequency signals on each amplifier path 62 together on output signal path 58 (e.g., as a combined radio-frequency signal provided to load 56). Multipath amplifier circuitry 54 may drive load 56 using the combined radio-frequency signal on output signal path 58.

The amplifier paths 62 in multipath amplifier circuitry 54 may include a first amplifier path 62M (sometimes also referred to herein as main amplifier path 62M or primary amplifier path 62M). An amplifier such as amplifier 64 may be disposed on main amplifier path 62M. Amplifier 64 is sometimes also referred to herein as main amplifier 64 or primary amplifier 64. Main amplifier 64 may amplify a radio-frequency signal on main amplifier path 62M while biased using a corresponding main amplifier bias voltage VBM.

The amplifier paths 62 in multipath amplifier circuitry 54 may also include a second amplifier path 62A (sometimes also referred to herein as auxiliary amplifier path 62A or secondary amplifier path 62A) coupled in parallel with main amplifier path 62M between input network 70 and output network 68 (e.g., between the input and output of multipath amplifier circuitry 54). An amplifier such as amplifier 66 may be disposed on auxiliary amplifier path 62A. Amplifier 66 is sometimes also referred to herein as auxiliary amplifier 66 or secondary amplifier 66. Auxiliary amplifier 66 may amplify a radio-frequency signal on auxiliary amplifier path 62A while biased using a corresponding auxiliary amplifier bias voltage VBA. In the example of FIG. 3, multipath amplifier circuitry 54 is illustrated as including only a single auxiliary amplifier path 62A for the sake of clarity. If desired, multipath amplifier circuitry 54 may include multiple auxiliary amplifier paths 62A each including a different respective auxiliary amplifier 66.

In practice, main amplifier 64 and auxiliary amplifier 66 are non-linear. As such, the output voltage of each amplifier increases linearly as a function of input power up until a certain power level, after which the amplifier becomes saturated and any further increase in input power does not produce a corresponding linear increase in output voltage. Main amplifier 64 may be configured or tuned to exhibit a linear response for a different range of input power levels and/or output power levels than auxiliary amplifier 66. Main amplifier 64 may, for example, be turned on and used to amplify a radio-frequency signal received over input signal path 60 up until a certain output power level, beyond which the main amplifier may no longer exhibit linear behavior. Once main amplifier 64 reaches this point, auxiliary amplifier 66 may be turned on and may help amplify the radio-frequency signal to reach higher power levels (e.g., power levels over which auxiliary amplifier 66 exhibits a linear response).

This may serve to maximize the range of output powers over which the multipath amplifier circuitry exhibits linear behavior while also ensuring that multipath amplifier circuitry 54 does not consume more power than needed, which increases the efficiency of the amplifier circuitry. Amplifiers 66 and 64 may, if desired, be different types of amplifiers that are optimized for amplifying signals at different power levels and/or with different characteristics. Amplifiers 66 and/or 64 may include, for example, a class A amplifier, a class AB amplifier, a class D amplifier, a class E amplifier, a class F amplifier, a class G amplifier, a class H amplifier, a class I amplifier, a class T amplifier, or other types of amplifiers.

Amplifiers 66 and 64 of two different types coupled together in this way using input network 70 and output network 68 are sometimes referred to collectively as a Doherty amplifier. Multipath amplifier circuitry 54 is sometimes also referred to herein as Doherty amplifier 54, Doherty amplifier circuitry 54, Doherty amplifier circuit 54, or multipath amplifier 54. Output network 68 is sometimes also referred to herein as Doherty output network 68 or Doherty output circuitry 68. Input network 70 is sometimes also referred to herein as Doherty input network 70 or Doherty input circuitry 70.

The precise turn on point of auxiliary amplifier 66 may be important for ensuring that multipath amplifier circuitry 54 exhibits a satisfactory level of efficiency. Auxiliary amplifier 66 may, for example, be turned on if/when main amplifier 64 reaches saturation (e.g., becomes voltage limited). Turning auxiliary amplifier 66 on too early may cause multipath amplifier circuitry 54 to consume excessive power (reducing efficiency). On the other hand, turning auxiliary amplifier 66 on too late sacrifices linearity performance and can introduce errors or non-idealities in the amplified radio-frequency signal output by multipath amplifier circuitry 54.

In some scenarios, auxiliary amplifier 66 is turned on based on the radio-frequency signal that is input to main amplifier 64. In these scenarios, a voltage detector may measure the voltage level of the radio-frequency signal prior to being amplified by main amplifier 64 and this measured voltage level is then fed to the bias terminal of auxiliary amplifier 66 (e.g., as bias voltage VBA). When the voltage level input to main amplifier 64 becomes sufficiently high, the voltage turns on auxiliary amplifier 66 and auxiliary amplifier 66 begins to contribute to the amplification performed by multipath amplifier circuitry 54. However, this type of auxiliary amplifier scheme is highly susceptible to changes in the impedance of load 56, process variations, and temperature. As such, if the impedance of load 56 varies excessively from a nominal impedance, multipath amplifier circuitry 54 exhibits excessive process variation, or the temperature of multipath amplifier circuitry 54 varies excessively from a nominal temperature, auxiliar amplifier 66 will be turned on too early (e.g., limiting efficiency) or too late (e.g., limiting performance).

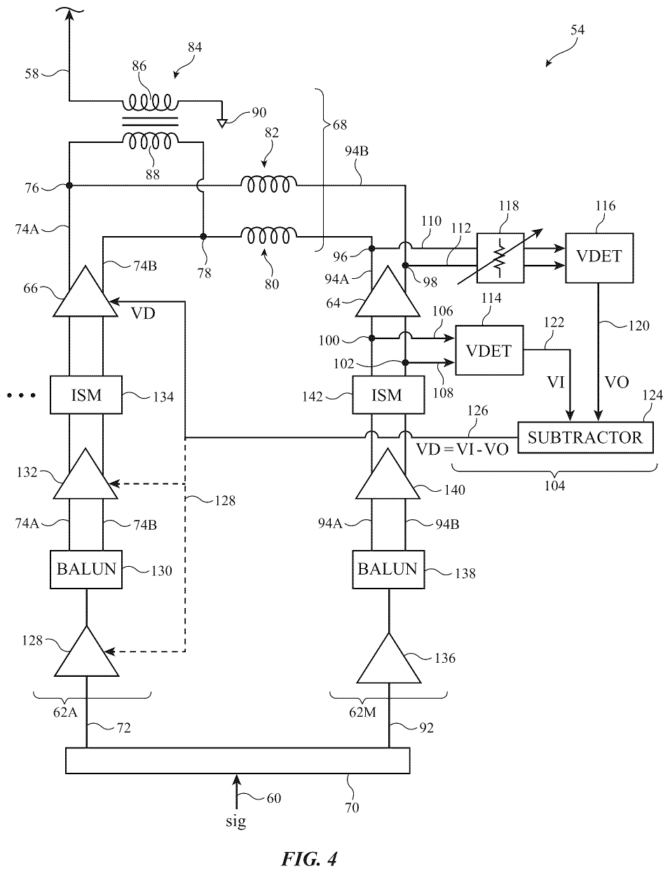

To mitigate these issues, main amplifier path 62M may include adaptive bias circuitry. The adaptive bias circuitry may detect and utilize both the output of main amplifier 64 and the input of main amplifier 64 to bias and turn on auxiliary amplifier 66. FIG. 4 is a circuit diagram showing one example of how multipath amplifier circuitry 54 may include adaptive biasing circuitry for auxiliary amplifier 66.

As shown in FIG. 4, input network 70 may receive a radio-frequency signal (sig) over input signal path 60. Input network 70 may split radio-frequency signal sig between auxiliary amplifier path 62A and main amplifier path 62M. Input network 70 may be, as one example, a quadrature hybrid input network that passes radio-frequency signal sig onto auxiliary amplifier path 62A with a first phase (e.g., zero degrees) and that passes radio-frequency signal sig onto main amplifier path 62B with a second (quadrature) phase that is 90 degrees from the first phase. This is illustrative and, in general, input network 70 may include any desired circuitry.

In the example of FIG. 4, auxiliary amplifier path 62A and main amplifier path 62M are differential paths that convey differential signals to auxiliary amplifier 66 and main amplifier 64 respectively. As such, auxiliary amplifier path 62A may include a differential signal path 74 that includes a differential pair of signal lines 74A and 74B. Auxiliary amplifier 66 may be disposed on differential signal path 74. Auxiliary amplifier path 62A may also include a balun 130 that couples differential signal path 74 to a first output terminal of input network 70. Balun 130 may receive radio-frequency signal sig from input network 70 as a single-ended signal and may convert radio-frequency signal sig into a differential signal pair on signal lines 74A and 74B.

Similarly, main amplifier path 62M may include a differential signal path 94 that includes a differential pair of signal lines 94A and 94B. Main amplifier 64 may be disposed on differential signal path 94. Main amplifier path 62M may also include a balun 138 that couples differential signal path 94 to input network 70. Balun 138 may receive radio-frequency signal sig from input network 70 as a single-ended signal (e.g., 90 degrees out of phase with respect to the signal received by balun 130) and may convert radio-frequency signal sig into a differential signal pair on signal lines 74A and 74B. This example is illustrative and non-limiting. Alternatively, auxiliary amplifier path 62A may be a single-ended signal path that conveys a single-ended signal to auxiliary amplifier 66 and main amplifier path 62M may be a single-ended signal path that conveys a single-ended signal to main amplifier 64.

In the example of FIG. 4, auxiliary amplifier path 62A also includes one or more additional auxiliary amplifier (gain) stages such as amplifiers 132 and 128 and includes impedance matching circuitry such as interstage matching network (ISM) 134. Amplifier 128 may couple input circuitry 70 to the input of balun 130. Balun 130 may be coupled in series between the output of amplifier 128 and the input of amplifier 132. Amplifier 132 may be coupled in series between the output of balun 130 and the input of ISM 134. ISM 134 may be coupled in series between the output of amplifier 132 and the input of auxiliary amplifier 66. ISM 134 may help to match the output impedance of amplifier 132 to the input impedance of auxiliary amplifier 66. Amplifiers 132 and 128 may provide auxiliary amplification to radio-frequency signal sig in addition to auxiliary amplifier 66. Amplifiers 132 and 128 may, for example, be turned on if/when auxiliary amplifier 66 is turned on.

Similarly, main amplifier path 62M may include one or more additional main amplifier (gain) stages such as amplifiers 140 and 136 and/or may include impedance matching circuitry such as interstage matching network (ISM) 142. Amplifier 136 may couple input network 70 to the input of balun 138. Balun 138 may be coupled in series between the output of amplifier 136 and the input of amplifier 140. Amplifier 140 may be coupled in series between the output of balun 138 and the input of ISM 142. ISM 142 may be coupled in series between the output of amplifier 140 and the input of main amplifier 64. ISM 142 may help to match the output impedance of amplifier 140 to the input impedance of main amplifier 64. Amplifiers 140 and 136 may provide auxiliary amplification to radio-frequency signal sig in addition to main amplifier 64.

This example is illustrative and non-limiting. If desired, main amplifier path 62M may include more than three amplifiers and/or any other desired radio-frequency circuitry between input network 70 and output network 68. If desired, amplifier 140, ISM 142, and/or amplifier 136 may be omitted from main amplifier path 62M. If desired, auxiliary amplifier path 62A may include more than three amplifiers and/or any other desired radio-frequency circuitry between input network 70 and output network 68. If desired, amplifier 128, ISM 134, and/or amplifier 132 may be omitted from auxiliary amplifier path 62A.

In the example of FIG. 4, output network 68 includes a transformer 84 that couples both main amplifier path 62M and auxiliary amplifier path 62A to output signal path 58. Transformer 84 may, for example, include a first (primary) winding 88 and a second (secondary) winding 86 that is electromagnetically coupled to primary winding 88. Primary winding 88 may extend from a first terminal that is coupled to signal line 74A to an opposing second terminal that is coupled to signal line 74B of auxiliary amplifier path 62A. Secondary winding 86 may extend from a third terminal that is coupled to output signal path 58 to an opposing fourth terminal that is coupled to a reference potential such as ground 90.

Signal line 94A of main amplifier path 62M may be coupled to node 78 on signal line 74B of auxiliary amplifier path 62A and thus to the output of auxiliary amplifier 66 and to the second terminal of primary winding 88. If desired, output network 68 may include a coupling inductor such as inductor 80 that couples signal line 94A to node 78. Signal line 94B of main amplifier path 62M may be coupled to node 76 on signal line 74A of auxiliary amplifier path 62A and thus to the output of auxiliary amplifier 66 and to the first terminal of primary winding 88. If desired, output network 68 may include a coupling inductor such as inductor 82 that couples signal line 94B to node 76.

Transformer 84 may receive radio-frequency signal sig as amplified by main amplifier path 62M (e.g., through coupling inductors 80 and 82) and, when auxiliary amplifier 66 is active, may receive radio-frequency signal sig as amplified by auxiliary amplifier path 62A. Transformer 84 may combine the amplified radio-frequency signals onto output signal path 58. Transformer 84 may, for example, form a balun that converts the radio-frequency signals from differential signals into a single-ended signal on output signal path 58. This is illustrative and non-limiting and, in general, output network 68 may include any desired circuitry that combines the radio-frequency signals on auxiliary amplifier path 62A and main amplifier path 62M onto output signal path 58. Output signal path 58 and/or input signal path 60 may be a differential signal path if desired.

Multipath amplifier circuitry 54 may include adaptive bias circuitry coupled to main amplifier path 62M such as adaptive bias circuit 104 (sometimes also referred to herein as adaptive bias circuitry 104, adaptive biasing circuit 104, adaptive biasing circuitry 104, dynamic bias circuit 104, or dynamic biasing circuit 104). Although adaptive bias circuit 104 is sometimes also referred to herein as forming a part of main amplifier path 62M, adaptive bias circuit 104 may be used to power (bias) auxiliary amplifier path 62A. Adaptive bias circuit 104 may be coupled to signal lines 94A and 94B around main amplifier 64.

As shown in FIG. 4, adaptive bias circuit 104 may include a first voltage detection circuit such as voltage detector (VDET) 114 and may include a second voltage detection circuit such as voltage detector 116. Voltage detector 114 may be operably coupled to the input of main amplifier 64 and is sometimes referred to herein as input voltage detector 114. The input of voltage detector 114 may, for example, be coupled to node 100 on signal line 94A (e.g., between main amplifier 64 and ISM 142) over tap line 106 and may be coupled to node 102 on signal line 94B (e.g., between main amplifier 64 and ISM 142) over tap line 108. Tap lines 106 and 108 may be communicatively coupled to signal lines 94A and 94B using one or more signal splitters, signal couplers, etc. Alternatively, voltage detector 114 may be disposed on signal lines 94A and 94B between ISM 142 and main amplifier 64. Voltage detector 114 may measure (e.g., generate, output, identify, detect, etc.) the voltage of the radio-frequency signal sig that is input to main amplifier 64 (sometimes also referred to herein as the input voltage level VI of main amplifier 64).

On the other hand, voltage detector 116 may be operably coupled to the output of main amplifier 64 and is sometimes referred to herein as output voltage detector 116. The input of voltage detector 116 may, for example, be coupled to node 96 on signal line 94A (e.g., between main amplifier 64 and inductor 80) over tap line 110 and may be coupled to node 98 on signal line 94B (e.g., between main amplifier 64 and inductor 82) over tap line 112. Tap lines 110 and 112 may be communicatively coupled to signal lines 94A and 94B using one or more signal splitters, signal couplers, etc. Alternatively, voltage detector 116 may be disposed on signal lines 94A and 94B between main amplifier 64 and output network 68. Voltage detector 116 may measure (e.g., generate, output, identify, detect, etc.) the voltage of the amplified radio-frequency signal sig that is output by main amplifier 64 (sometimes also referred to herein as the output voltage level VO of main amplifier 64). If desired, a signal attenuator such as attenuator 118 may attenuate output voltage level VO to compensate for the gain produced by main amplifier 64. Attenuator 118 may be adjustable (e.g., based on the present setting of main amplifier 64).

Adaptive bias circuit 104 may also include subtraction (difference) circuitry such as subtractor 124. Subtractor 124 may be implemented using analog circuitry, one or more digital logic gates, and/or any other desired subtractor circuitry. Subtractor 124 may have a first input coupled to the output of voltage detector 114 over voltage detection path 122. Subtractor 124 may receive, over voltage detection path 122, the input voltage level VI measured by voltage detector 114. Subtractor 124 may also have a second input coupled to the output of voltage detector 116 over voltage detection path 116. Subtractor 124 may receive, over voltage detection path 120, the output voltage level VO measured by voltage detector 116. Subtractor 124 may generate (e.g., output, produce, etc.) a difference voltage VD that corresponds to the difference between the input and output voltage envelopes of main amplifier 64. Subtractor 124 may, for example, generate difference voltage VD by subtracting output voltage level VO from input voltage level VI.

The output of subtractor 124 may be coupled to the bias terminal of auxiliary amplifier 66 over bias voltage path 126. Subtractor 124 may provide difference voltage VD to the bias terminal of auxiliary amplifier 66 over bias voltage path 126. Subtractor 124 may bias (power) auxiliary amplifier 66 using difference voltage VD (e.g., difference voltage VD may form bias voltage VBA of FIG. 3). Auxiliary amplifier 66 may amplify the radio-frequency signal sig on auxiliary amplifier path 62A using difference voltage VD (e.g., while the auxiliary amplifier is biased using difference voltage VD). If desired, bias voltage path 126 may also be coupled to the bias terminals of amplifiers 132 and/or 128, as shown by arrow 128. In these configurations, adaptive bias circuit 104 may also turn on, power, and bias, amplifiers 132 and 128 using difference voltage VD. This may, for example, cause amplifiers 128 and 132 to turn on and begin amplifying signals whenever auxiliary amplifier 66 turns on and begins amplifying signals, which can reduce quiescent current and improve the efficiency.

In this way, adaptive bias circuit 104 may generate difference voltage VD based on the present operating characteristics of main amplifier 64 given its operating temperature, process variation, and the impedance of load 56 (FIG. 3). Subtractor 124 may subtract the envelope of the signal output by main amplifier 64 (e.g., output voltage level VO) from the envelope of the signal input to main amplifier 64 (e.g., input voltage level VI) to generate a difference voltage VD that forms an adaptive bias signal for auxiliary amplifier path 62A that varies based on temperature, process variation, and/or the impedance of load 56. The magnitude of difference voltage VD may, for example, track the saturation point of main amplifier 64 over temperature, process variation, and the impedance of load 56 to ensure that auxiliary amplifier path 62A is turned on neither too early nor too late given present operating conditions, which may vary over time. Put differently, adaptive bias circuit 104 may automatically detect (e.g., in real time) when main amplifier 64 enters saturation and can begin to power on the amplifiers in auxiliary amplifier path 62A at that input power level, regardless of antenna loading, operating temperature, etc.

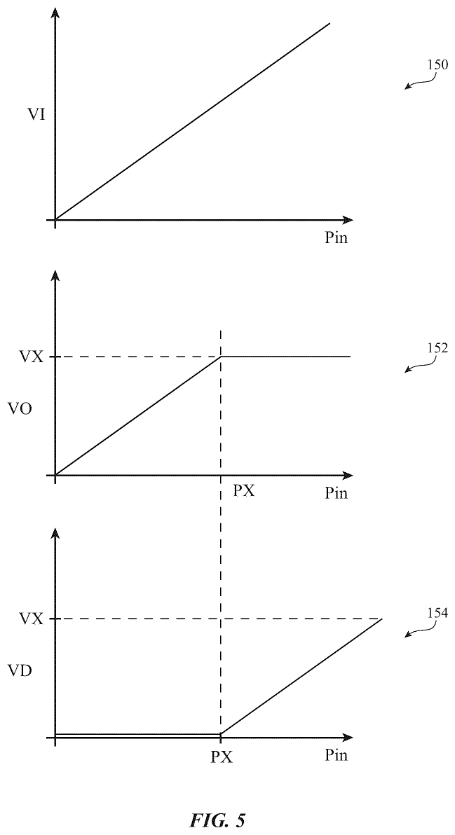

FIG. 5 illustrates the various voltages operated on by adaptive bias circuit 104. Curve 150 of FIG. 5 plots input voltage level VI to main amplifier 64 as a function of the input power level Pin of the radio-frequency signal sig that is input to main amplifier 64. As shown by curve 150, input voltage level VI may increase in a linear manner as input power level Pin increases. Voltage detector 114 (FIG. 4) may detect this input voltage level VI and may provide the detected input voltage level to subtractor 124.

Curve 152 of FIG. 5 plots output voltage level VO of main amplifier 64 as a function of the input power level Pin of the radio-frequency signal sig that is input to main amplifier 64. As shown by curve 152, output voltage level VO may increase in a linear manner as input power level Pin increases up until power level PX. At input power levels greater than power level PX, main amplifier 64 may become saturated, limiting output voltage level VO to voltage VX as input power level increases beyond power level PX. Power level PX may be, for example, the saturation power level of main amplifier 64 or another power level near saturation such as the saturation power level of main amplifier 64 minus 6 dB. Voltage detector 116 (FIG. 4) may detect this output voltage level VO (e.g., after suitable attenuation by attenuator 118 to compensate for any associated voltage offsets that would otherwise be produced by subtractor 124 and that would otherwise cause the auxiliary amplifier path to turn on too early). Voltage detector 116 may provide the detected output voltage level to subtractor 124.

Curve 154 of FIG. 5 plots the difference voltage VD produced by subtractor 124 as a function of input power level Pin. Subtractor 124 may generate difference voltage VD (curve 154) as the difference between the measured input voltage level VI (curve 150) and the measured output voltage level VO (curve 152) (e.g., VD=VI−VO). Adaptive bias circuit 104 may supply difference voltage VD (curve 154) to the amplifiers in auxiliary amplifier path 62A. When difference voltage VD is at a magnitude of zero (e.g., at input power levels Pin less than power level PX), the amplifiers in auxiliary amplifier path 62A are biased using a bias voltage of zero volts, which prevents the amplifiers from turning on and amplifying signals (e.g., the amplifiers are inactive, disabled, or turned off). Once difference voltage VD increases beyond power level PX, difference voltage VD powers on the amplifiers in auxiliary amplifier path 62A and the amplifiers begin to amplify signals (e.g., the amplifiers are active, enabled, or turned on). Because adaptive bias circuit 104 automatically begins producing a non-zero difference voltage VD when input power level Pin reaches power level PX regardless of temperature/process variation and output load impedance, adaptive bias circuit 104 may turn on auxiliary amplifier path 62A when main amplifier 64 has actually reached saturation, which may serve to increase the efficiency of the multipath amplifier circuitry without sacrificing linearity performance.

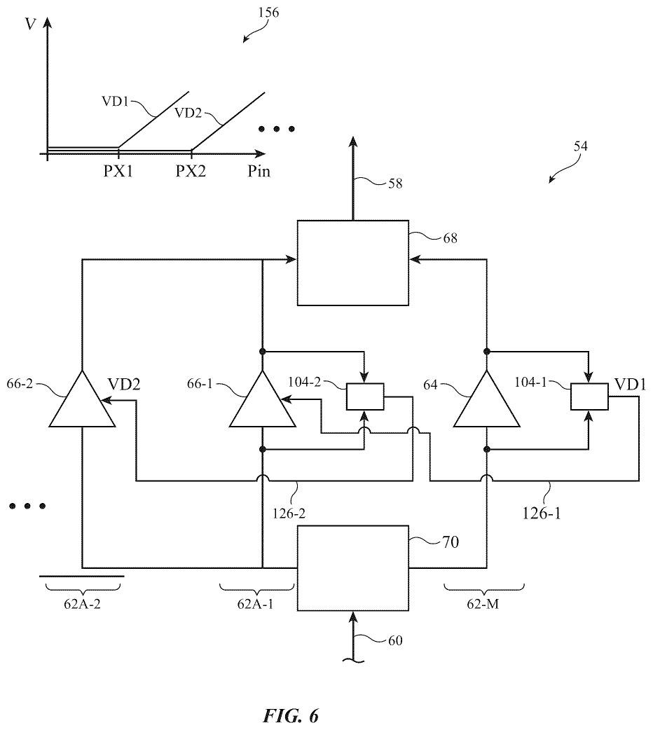

FIG. 6 illustrates another example in which multipath amplifier circuitry 54 includes multiple auxiliary amplifier paths 62A. As shown in FIG. 6, multipath amplifier circuitry 54 may include a first auxiliary amplifier path 62A-1 and a second auxiliary amplifier path 62A-2 coupled in parallel with main amplifier path 62M between input network 70 and output network 68. Auxiliary amplifier path 62A-1 may include a first auxiliary amplifier 66-1. Auxiliary amplifier path 62A-2 may include a second auxiliary amplifier 66-2 (e.g., configured or tuned to exhibit linearity over a different range of power levels than auxiliary amplifier 66-1).

Multipath amplifier circuitry 54 may include an adaptive bias circuit 104-1 (see, e.g., adaptive bias circuit 104 of FIG. 3) coupled to main amplifier path 62M around main amplifier 64. Adaptive bias circuit 104-1 may measure the input and output voltages of main amplifier 64 and may generate a corresponding difference voltage VD1 based on the input and output voltages of main amplifier 64 (e.g., as described above in connection with FIG. 4).

Adaptive bias circuit 104-1 may be coupled to the bias terminal of auxiliary amplifier 66-1 over bias voltage path 126-1. Adaptive bias circuit 104-1 may bias auxiliary amplifier 66-1 using difference voltage VD1. Difference voltage VD1 may turn on auxiliary amplifier 66-1 when main amplifier 64 reaches its saturation point or 6 dB less than its saturation point, for example.

Multipath amplifier circuitry 54 may also include an adaptive bias circuit 104-2 (see, e.g., adaptive bias circuit 104 of FIG. 3) coupled to auxiliary amplifier path 62A-1 around auxiliary amplifier 66-1. Adaptive bias circuit 104-2 may measure the input and output voltages of auxiliary amplifier 66-1 and may generate a corresponding difference voltage VD2 based on the input and output voltages of auxiliary amplifier 66-1 (e.g., as described above in connection with FIG. 4). Adaptive bias circuit 104-2 may be coupled to the bias terminal of auxiliary amplifier 66-2 over bias voltage path 126-2. Adaptive bias circuit 104-2 may bias auxiliary amplifier 66-2 using difference voltage VD2. Difference voltage VD2 may turn on auxiliary amplifier 66-2 when auxiliary amplifier 66-1 reaches its saturation point or 6 dB less than its saturation point, for example.

Plot 156 of FIG. 6 illustrates difference voltages VD1 and VD2 as a function of the input power level Pin of main amplifier 64 and auxiliary amplifier 66-1, respectively. As shown by plot 156, difference voltage VD1 may track the saturation point of main amplifier 64 and may turn on auxiliary amplifier 66-1 once the input power level of main amplifier 64 has reached a first power level PX1. On the other hand, difference voltage VD2 may track the saturation point of auxiliary amplifier 66-1 and may turn on auxiliary amplifier 66-2 once the input power level of auxiliary amplifier 66-1 has reached a second power level PX2 that is higher than power level PX1. This may be generalized to any number of auxiliary amplifier paths (e.g., where each auxiliary amplifier path includes an adaptive bias circuit that generates a respective difference voltage VD to turn on and bias the next auxiliary amplifier path when its own auxiliary amplifier path reaches saturation).

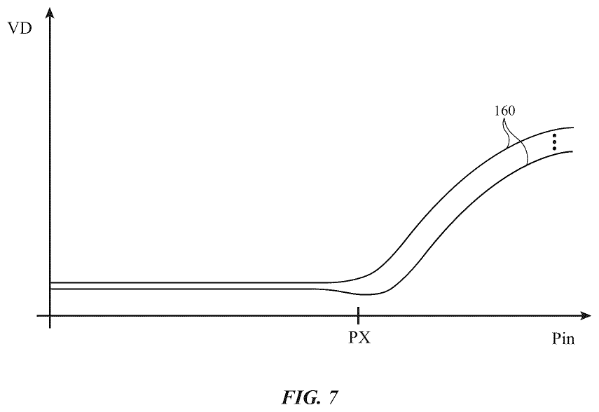

FIG. 7 plots the variation in the difference voltage VD as a function of input power level Pin produced by an adaptive bias circuit 104 under different loading conditions. Each curve 160 of FIG. 7 represents difference voltage VD as produced while load 56 exhibits a different impedance. As shown by curves 160, variation in the impedance of load 56 does not substantially affect the difference voltage VD output by adaptive bias circuit 104. In this way, adaptive bias circuit 104 may reliably bias and turn on an auxiliary amplifier path at an advantageous time or input power level regardless of the impedance of load 56. In implementations where load 56 is formed from an antenna 42 (FIG. 1), this means that multipath amplifier circuitry 54 may turn on and utilize its auxiliary amplifier path(s) at an advantageous time, even as external objects move towards, away from, and/or over the antenna. The example of FIG. 7 is illustrative and, in practice, curves 160 may have other shapes.

As used herein, the term “concurrent” means at least partially overlapping in time. In other words, first and second events are referred to herein as being “concurrent” with each other if at least some of the first event occurs at the same time as at least some of the second event (e.g., if at least some of the first event occurs during, while, or when at least some of the second event occurs). First and second events can be concurrent if the first and second events are simultaneous (e.g., if the entire duration of the first event overlaps the entire duration of the second event in time) but can also be concurrent if the first and second events are non-simultaneous (e.g., if the first event starts before or after the start of the second event, if the first event ends before or after the end of the second event, or if the first and second events are partially non-overlapping in time). As used herein, the term “while” is synonymous with “concurrent.”

The methods and operations described above in connection with FIGS. 1-6 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The methods and operations described above in connection with FIGS. 1-7 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The foregoing is illustrative and various modifications can be made to the described embodiments. The foregoing embodiments may be implemented individually or in any combination.

What is claimed is:

1. Amplifier circuitry comprising:
an input circuit;
an output circuit;
a first amplifier path coupled between the input and output circuits and having a first amplifier;
a second amplifier path coupled between the input and output circuits and having a second amplifier;
a first voltage detector operably coupled to an input of the first amplifier;
a second voltage detector operably coupled to an output of the first amplifier;
a subtractor having an input coupled to the first and second voltage detectors; and
a bias voltage path that couples an output of the subtractor to a bias terminal of the second amplifier.

2. The amplifier circuitry of claim 1, further comprising:
a signal attenuator coupled between the first amplifier path and the second voltage detector.

3. The amplifier circuitry of claim 1, further comprising:
a third amplifier path coupled between the input and output circuits in parallel with the first and second amplifier paths, the third amplifier path having a third amplifier;
a third voltage detector operably coupled to an input of the second amplifier;
a fourth voltage detector operably coupled to an output of the second amplifier;
an additional subtractor having an input coupled to the third and fourth voltage detectors; and
an additional bias voltage path that couples an output of the additional subtractor to a bias terminal of the third amplifier.

4. The amplifier circuitry of claim 3, wherein the input circuit is configured to split a radio-frequency signal between the first, second, and third amplifier paths, the subtractor is configured to turn on the second amplifier when the radio-frequency signal is incident upon the first amplifier within a first range of powers, and the additional subtractor is configured to turn on the third amplifier when the radio-frequency signal is incident upon the second amplifier within a second range of powers that is higher than the first range of powers.

5. The amplifier circuitry of claim 1, wherein the input circuit is configured to split a radio-frequency signal between the first and second amplifier paths, the first detector is configured to measure a first voltage level of the radio-frequency signal at the input of the first amplifier, the second detector is configured to measure a second voltage level of the radio-frequency signal at the output of the first amplifier, and the subtractor is configured to bias the second amplifier using a bias voltage equal to a difference between the first and second voltage levels.

6. The amplifier circuitry of claim 5, wherein the input circuit is configured to provide the radio-frequency signal to the first amplifier path at a first phase and is configured to provide the radio-frequency signal to the second amplifier path at a second phase that is 90 degrees from the first phase.

7. The amplifier circuitry of claim 1, wherein the first amplifier path comprises a first differential signal path having first and second signal lines, the first amplifier is disposed on the first and second signal lines, the second amplifier path includes a second differential signal path having third and fourth signal lines, and the second amplifier is disposed on the third and fourth signal lines.

8. The amplifier of claim 7, wherein the output circuit comprises a transformer that includes a primary winding coupled between the first and second signal lines and that includes a secondary winding coupled to an output of the amplifier circuitry.

9. The amplifier of claim 8, further comprising:
a first inductor that couples the third signal line to a first node on the first signal line; and
a second inductor that couples the fourth signal line to a second node on the second signal line.

10. The amplifier of claim 7, further comprising:
a first balun that couples the input circuit to the first and second signal lines; and
a second balun that couples the input circuit to the third and fourth signal lines.

11. The amplifier of claim 1, further comprising:
a third amplifier on the second amplifier path and coupled in series between the second amplifier and the input circuit, wherein the bias voltage path couples the output of the subtractor to a bias terminal of the third amplifier.

12. Amplifier circuitry comprising:
an input network;
an output network;
a primary amplifier path coupled between the input and output networks;
a first amplifier on the primary amplifier path;
an auxiliary amplifier path coupled between the input and output networks in parallel with the primary amplifier path;
a second amplifier on the auxiliary amplifier path; and
an adaptive biasing circuit configured to bias the second amplifier based on an output voltage level of the first amplifier and based on an input voltage level of the first amplifier.

13. The amplifier circuitry of claim 12, wherein the adaptive biasing circuit is configured to bias the second amplifier based on a difference between the input voltage level and the output voltage level of the first amplifier.

14. The amplifier circuitry of claim 13, wherein the adaptive biasing circuit is configured to generate a difference voltage based on the difference between the input voltage level and the output voltage level of the first amplifier and is configured to supply the difference voltage to a bias terminal of the second amplifier.

15. The amplifier circuitry of claim 14, wherein the adaptive biasing circuit comprises:
a first voltage detector coupled to the primary amplifier path between the first amplifier and the input network; and
a second voltage detector coupled to the primary amplifier path between the first amplifier and the output network.

16. The amplifier circuitry of claim 15, wherein the adaptive bias circuit further comprises:
a subtractor coupled to an output of the first voltage detector and an output of the second voltage detector, wherein the subtractor is configured to generate the difference voltage.

17. The amplifier circuitry of claim 16, wherein the adaptive biasing circuit further comprises:
a signal attenuator coupled between the second voltage detector and the primary amplifier path.

18. The amplifier circuitry of claim 12, further comprising:
an additional auxiliary amplifier path coupled between the input and output networks in parallel with the primary amplifier path and the auxiliary amplifier path;
a third amplifier on the additional auxiliary amplifier path; and
an additional adaptive biasing circuit configured to bias the third amplifier based on an additional output voltage level of the second amplifier and based on an additional input voltage level of the second amplifier.

19. The amplifier circuitry of claim 12, further comprising:
a third amplifier on the auxiliary amplifier path and coupled in series between the second amplifier and the input network, wherein the adaptive biasing circuit is configured to bias both the second amplifier and the third amplifier based on a difference between the input voltage level and the output voltage level of the first amplifier.

20. Wireless circuitry comprising:
an antenna; and
a power amplifier communicatively coupled to the antenna and configured to transmit a radio-frequency signal using the antenna, wherein the power amplifier includes
a signal splitter,
a signal combiner,
a first amplifier path coupled between the signal splitter and the signal combiner and having a first amplifier,
a second amplifier path coupled between the signal splitter and the signal combiner in parallel with the first amplifier path and having a second amplifier,
a first voltage detector configured to measure an input voltage of the first amplifier, and
a second voltage detector configured to measure an output voltage of the first amplifier, wherein the second amplifier is biased using a difference between the input voltage and the output voltage of the first amplifier.
